(19) United States
(12) Patent Application Publication
(10) Pub. No.: US 2011/0308456 A1
(43) Pub. Date: Dec. 22, 2011

(54) COATING APPARATUS

(75) Inventor: SHAO-KAI PEI, Tu-Cheng (TW)

(73) Assignee: HON HAI PRECISION INDUSTRY CO., LTD., Tu-Cheng (TW)

(21) Appl. No.: 12/982,901

(22) Filed: Dec. 31, 2010

(30) Foreign Application Priority Data
Jun. 21, 2010 (TW) 99120163

(51) Int. Cl. C23C 16/455; C23C 16/458; C23C 16/00

(52) U.S. Cl. 118/719; 118/730; 118/724

(57) ABSTRACT

A coating apparatus for coating a number of workpieces includes a deposition chamber, a reaction assembly, and a driving assembly. The deposition chamber includes a housing defining a cavity. The reaction assembly is received in the deposition chamber and includes an outer barrel, an inner barrel, a number of nozzles, and a number of pipes. The housing and the outer barrel define a reaction chamber therebetween. The outer barrel includes a main body and two protruding portions extending from the main body. The workpieces are positioned on the protruding portions. The main body and the inner barrel define a first room therebetween. The inner barrel defines a second room. The pipes communicate the second room with the reaction chamber. The nozzles communicate the first room with the reaction chamber. The driving assembly is connected to the reaction assembly and configured for rotating the reaction assembly in the cavity.

### BACKGROUND

1. Technical Field

The present disclosure relates to coating technologies and, particularly, to a coating apparatus.

2. Description of Related Art

Generally, a chemical vapor deposition (CVD) apparatus is used to apply a single coating using one material. When workpieces need to be coated more than once and with different materials, then the workpieces should be moved from one CVD apparatus to another CVD apparatus. This is inconvenient and can easily cause the workpieces to be contaminated.

Therefore, what is needed is to provide a coating apparatus, which can overcome the above-mentioned problems.

### BRIEF DESCRIPTION OF THE DRAWINGS

FIG. 1 is an assembled, isometric view of a coating apparatus including a deposition chamber and a reaction assembly, according to one embodiment.

FIG. 2 is an exploded, isometric view of the coating apparatus of FIG. 1.

FIG. 3 is an exploded, isometric view of the deposition chamber of the coating apparatus of FIG. 1.

FIG. 4 is an isometric view of the reaction assembly of the coating apparatus of FIG. 1.

FIG. 5 is similar to FIG. 4, but viewing from another angle.

FIG. 6 is an isometric, cut-away view of the coating apparatus of FIG. 1.

FIG. 7 is a cross-sectional view of the coating apparatus of FIG. 1.

### DETAILED DESCRIPTION

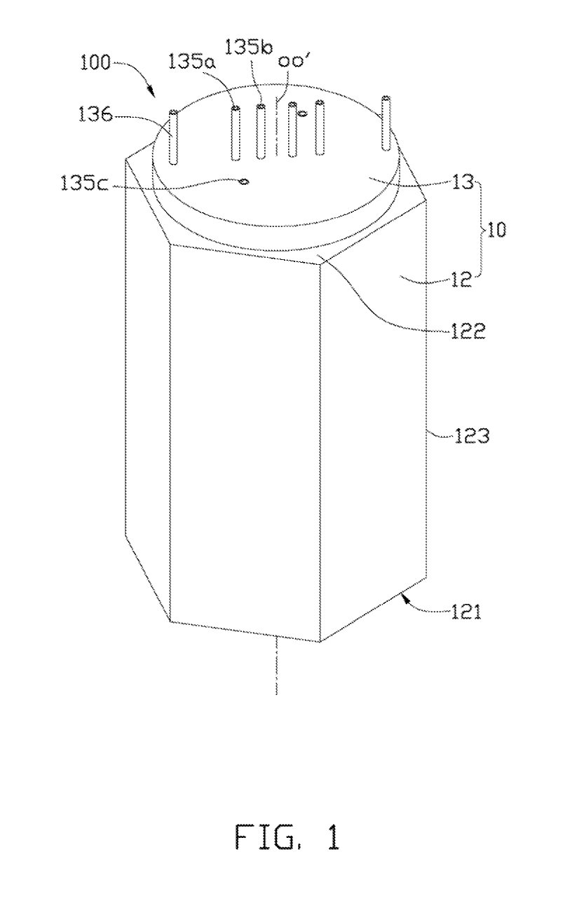

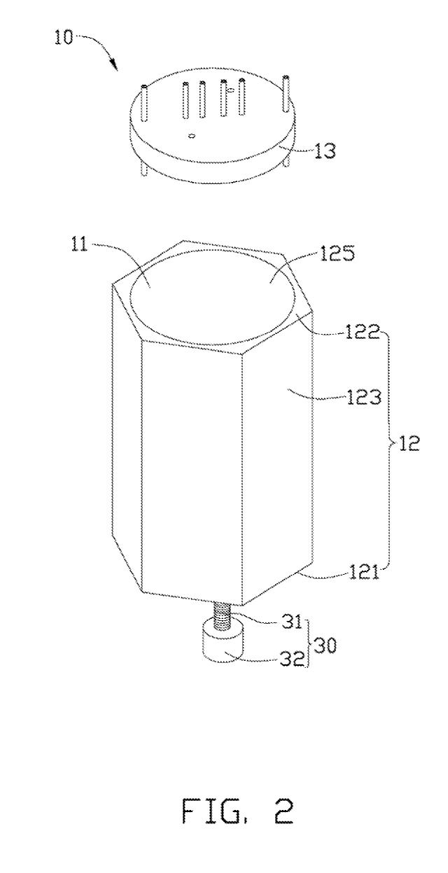

Referring to FIGS. 1-3, a coating apparatus 100 for forming at least two coatings on a number of workpieces (not shown), according to one embodiment, includes a deposition chamber 10, a reaction assembly 20 received in the deposition chamber 10, a driving assembly 30 configured for driving the reaction assembly 20 to rotate relative to the deposition chamber 10, and a controller 40 electrically connected to the driving assembly 30 and the reaction assembly 20.

The deposition chamber 10 may be made of metal and defines a cavity 11. The deposition chamber 10 includes a housing 12 having the cavity 11, and a cover 13 covers an end of the housing 12.

The housing 12 has a hexagonal cross-section. The housing 12 includes a bottom wall 121, a top wall 122 opposite to the bottom wall 121, and six connection sidewalls 123 connecting the top wall 122 to the bottom wall 121. The bottom wall 121 defines a first through hole 124 positioned substantially at a center of the bottom wall 121. The first through hole 124 is in communication with the cavity 11. The top wall 122 defines a circular opening 125 in communication with the cavity 11.

The cover 13 includes a discoid body 131, a first annular flange 132 extending from the discoid body 131, and a second annular flange 133 extending from the first flange 132. The first flange 132 and the second flange 133 are concentric with the body 131. The diameter of the first flange 132 is smaller than that of the body 131, but larger than the diameter of the second flange 133. The diameter of the body 131 is substantially equal to that of the opening 125. The body 131 can cover the housing 12 and seal the opening 125.

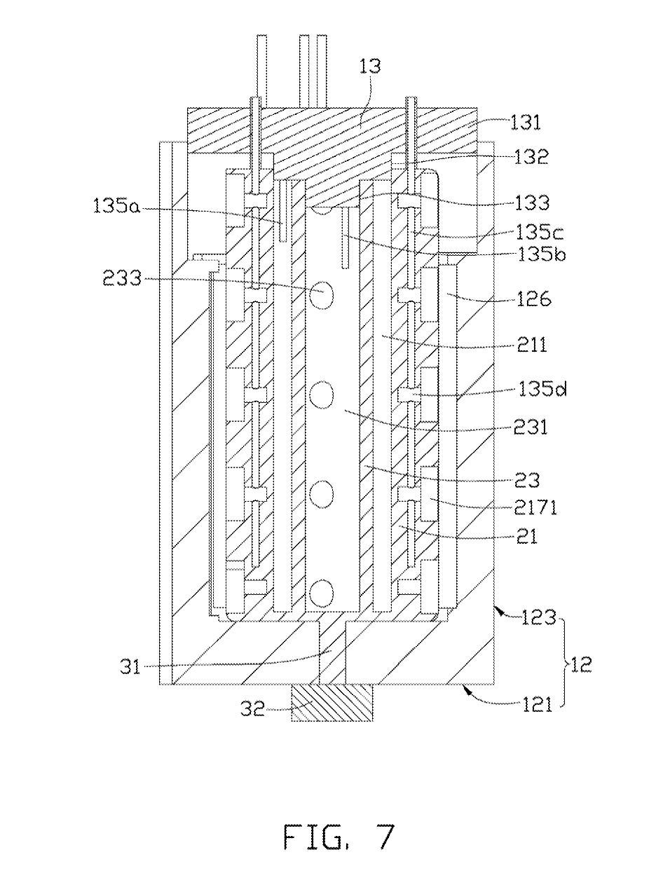

The cover 13 further defines six gas inlets 134 defined through the first flange 132, the second flange 133, and the body 131, for receiving six corresponding gas pipes 135 therein. The six gas inlets 134 are substantially arranged in a line. In detail, the six gas pipes 135 include two first gas pipes 135a mounted on the first flange 132 for letting in a first reaction gas, two second gas pipes 135b mounted on the second flange 133 for letting in a second reaction gas, and two vacuum pipes 135c mounted on the first flange 132 and adjacent to the first gas pipes 135a. Each vacuum pipe 135c includes a number of connectors 135d (see FIG. 7) equidistantly mounted thereon. A plurality of pumps (not shown) outside the housing 12 is respectively connected to the six gas pipes 135. The pumps are configured to hold the workpieces with suction from the vacuum pipes 135c, and also to provide different gas materials to the reaction assembly 20 through the first gas pipes 135a and the second gas pipes 135b.

Furthermore, two heaters 136 are mounted on the body 131 and face the reaction assembly 20. The two heaters 136 are configured to heat in the inside of the reaction assembly 20. In the present embodiment, the heaters 136 are heat pipes.

The driving assembly 30 is a servomotor and includes a first stator 31 and a first rotor 32 extending from the first stator 31. The first stator 31 is fixed outside the deposition chamber 10. The first rotor 32 engages with the first through hole 124 so that the driving assembly 30 can be connected to the reaction assembly 20. The reaction assembly 20 rotates relative to the housing 12 with the rotation of the first rotor 32.

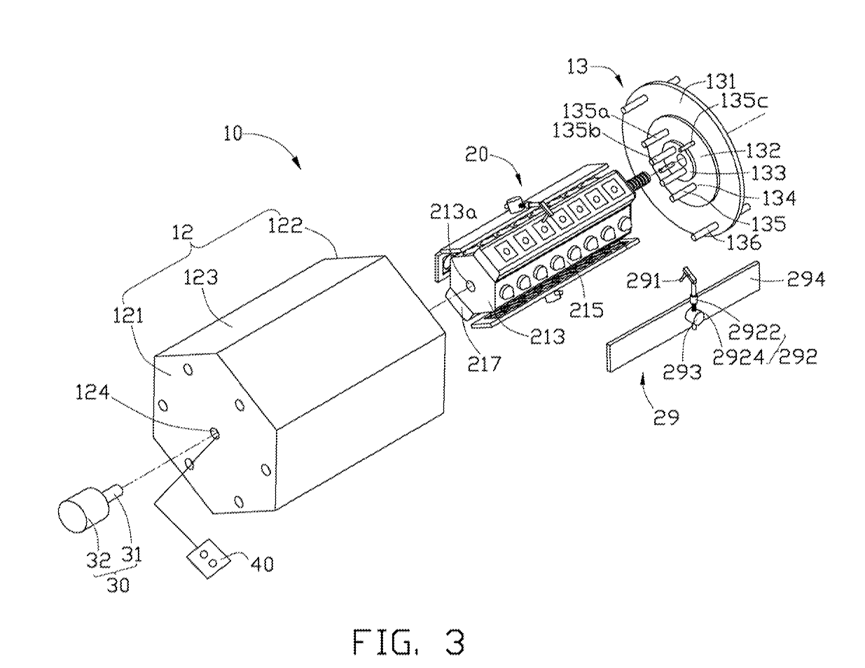

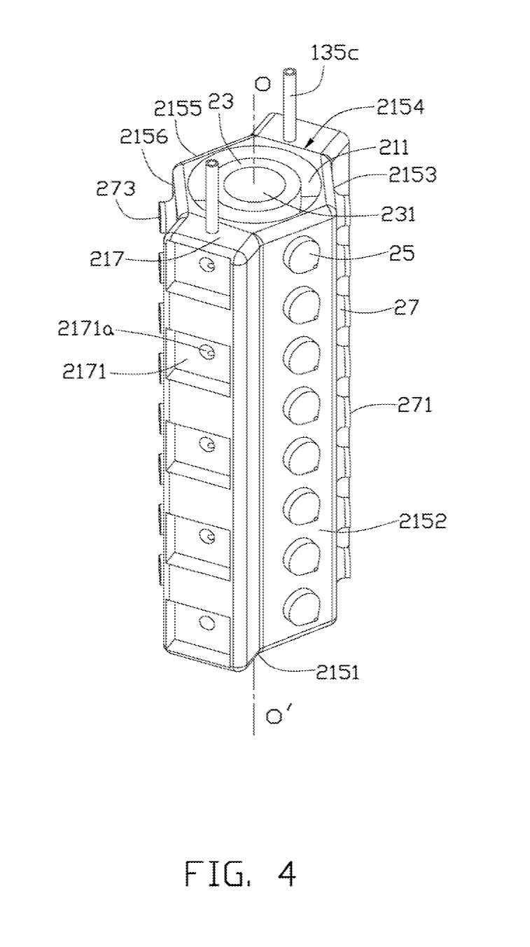

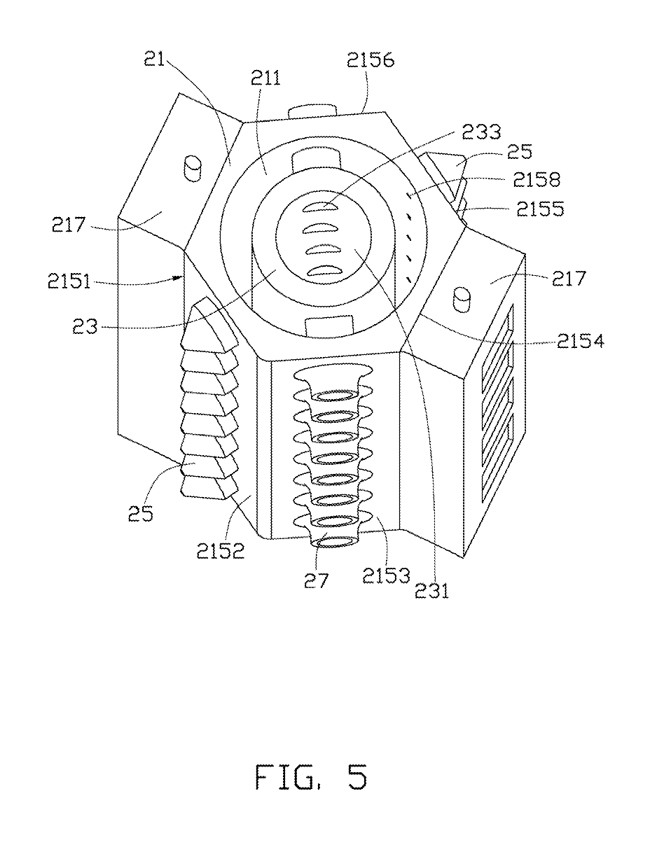

Referring to FIGS. 4-5, the reaction assembly 20 is received in the cavity 11. The reaction assembly 20 is coaxial with the housing 12. The reaction assembly 20 includes an outer barrel 21, an inner barrel 23, a plurality of nozzles 25, a plurality of pipes 27, and four shielding members 29 (see FIG. 3). The housing 12 and the outer barrel 21 cooperatively define a reaction chamber 126 (see FIG. 7) therebetween. The inner barrel 23 is coaxial with the outer barrel 21. The outer barrel 21 and the inner barrel 23 cooperatively define a first room 211 therebetween. The first flange 132 covers the outer barrel 21 and seals the first room 211. The heaters 136 are received in the reaction chamber 126.

The outer barrel 21 includes a bottom plate 213 (see FIG. 3), a main body 215 perpendicularly extending from the bottom plate 213, two protruding portions 217 radially extending from the main body 215.

The bottom plate 213 defines a fixing hole 213a substantially at the center of the bottom plate 213, for connecting the first stator 31 of the driving assembly 30 to the outer barrel 21.

The main body 215 is substantially a hollow hexagonal prism and includes a first sidewall 2151, a second sidewall 2152, a third sidewall 2153, a fourth sidewall 2154, a fifth sidewall 2155, and a sixth sidewall 2156 connected to each other end to end. The first sidewall 2151 is approximately parallel to the fourth sidewall 2154. The second sidewall 2152 is approximately parallel to the fifth sidewall 2155. The third sidewall 2153 is approximately parallel to the sixth sidewall 2156.

The second sidewall 2152 and the fifth sidewall 2155 define a number of second through holes 2158 corresponding to the plurality of nozzles 25.

The protruding portions 217 extend from the first sidewall 2151 and the fourth sidewall 2154, respectively. Each protruding portion 217 defines a plurality of receiving grooves 2171 in an outer surface thereof for receiving the workpieces. Each receiving groove 2171 defines a vacuum hole 2171a on the bottom surface thereof. The vacuum holes 2171a are communicated with the vacuum pipes 135c by the connectors 135d, to communicate with the pump. As such, when the pump works, the workpieces received in the second groove 2171 can be held in place by suction.

The inner barrel 23 is a hollow cylinder. The inner barrel 23 defines a second room 231. The inner barrel 23 further defines a number of third through holes 233 in communication with the second room 231. The third through holes 233 are arranged in two lines along the central axis OO′ of the housing 12, corresponding to the third sidewall 2153 and the sixth sidewall 2156. The second flange 133 covers the inner barrel 23 and seals the second room 231.

The nozzles 25 are arranged in two lines along the central axis OO′. A line of nozzles 25 are fixed to the second sidewall 2152 extending outwards from the first room 211, and the other line of nozzles 25 are fixed to the fifth sidewall 2155 extending outwards from the first room 211.

The pipes 27 are arranged in two lines along a direction parallel to the central axis OO′. An end of each pipe 27 is fixed to the inner barrel 23, and in communication with a corresponding third through hole 233. The other end of each pipe 27 runs through the outer barrel 21 to be exposed in the reaction chamber 126. In this embodiment, the pipes 27 include a number of first pipes 271 and a number of second pipes 273. The first pipes 271 are arranged along a first line and extend from the third sidewall 2153 toward and terminating at the corresponding third through holes 233. The second pipes 273 are arranged along a second line and extend from the sixth sidewall 2156 toward and terminating at the corresponding third through holes 233. As a result, the pipes 27 communicate the second room 231 with the reaction chamber 126.

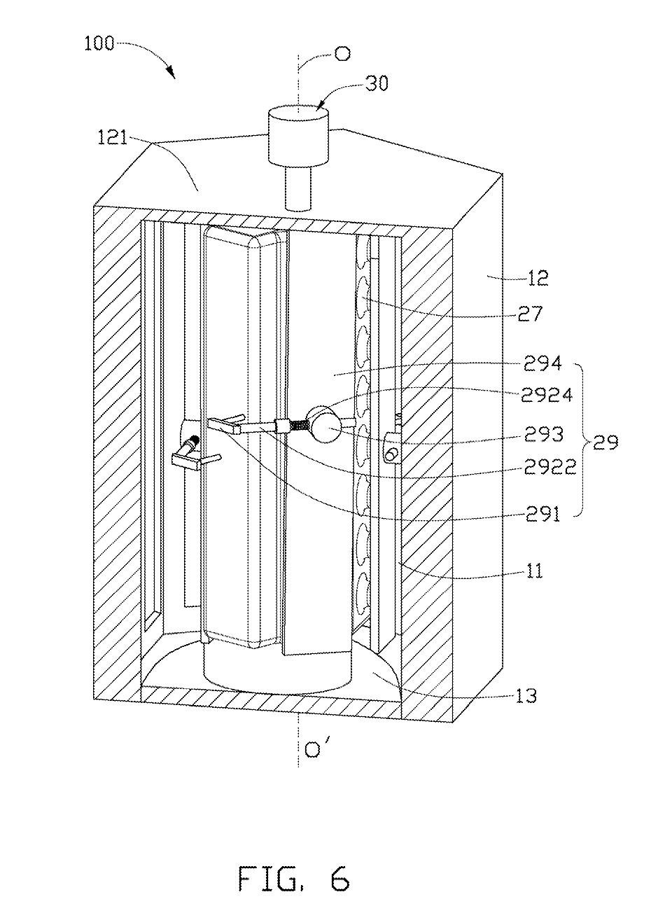

Referring to FIG. 6-7, the four shielding members 29 each include a connecting rod 291, an actuator 292, a lead cap 293, and a shielding plate 294.

Each two shielding members 29 are mounted on a corresponding protruding portion 217, with the shielding plates 294 substantially parallel to the second sidewall 2152, the sixth sidewall 2156, the third sidewall 2153, and the fifth sidewall 2155. The connecting rod 291 of each shielding members 29 is fixedly connected to the corresponding protruding portion 217 and is bent toward the adjacent sidewall. The actuator 292 includes a second stator 2922 and a second rotor 2924 extending from the second stator 2922. The second stator 2922 is fixedly connected to the connecting rod 291. The second rotor 2924 is a lead screw. The lead cap 293 is fixed on the shielding plate 294. The shielding plate 294 faces a corresponding one of the second sidewall 2152, the sixth sidewall 2156, the third sidewall 2153, and the fifth sidewall 2155 and covers a line of pipes 27, or a line of nozzles 25. The second rotor 2924 threadedly engages with the screw cap 294. The screw cap 294 moves along the second rotor 2924 with the rotation of the second rotor 2924. The shielding plate 294 moves with the movement of the screw cap 294 to cover or uncover the nozzles 25 or the pipes 27.

The controller 40 is electrically connected to the pumps, the driving assembly 30, the actuator 292, and the heaters 136. The controller 40 is configured for controlling the pump to evacuate any air in the reaction chamber 126, controlling the driving assembly 30 to drive the first rotor 32 to rotate, controlling the actuator 292 to drive the second rotor 2924 to rotate, controlling the heaters 136 to operate, and controlling the pipes 27 to introduce the first reaction gas to the first room 211, and controlling the nozzles 25 to introduce the second reaction gas to the second room 231, at different times, thereby applying different coatings on the workpieces in succession.

At the beginning of chemical vapor deposition for coating the workpieces, the reaction chamber 126 is filled with a common gas, for example, SiH4. That is, a gas that will be used in both coating processes to react with the first reaction gas then the second reaction gas. The shielding plates 296 cover the openings of the pipes 27 and the openings of the nozzles 25.

Next, the other two shielding plates 296 are moved to uncover the openings of the nozzles 25. The first reaction gas, e.g. hydrogen gas (H₂), is introduced through the first gas pipes 135 into the first room 211. As pressure of the first reaction gas in the first room 211 increases, the first reaction gas continues on into the reaction chamber 126 through the second through hole 2158 and the nozzles 25. The resultant of the reaction between the first reaction gas and the common gas is deposited on the workpieces as a first coating. In this embodiment, the reaction forming the first coating may be expressed as follows: SiH₄+H₂═Si+3H₂.

When the first coating is finished, the controller 40 controls the corresponding two shielding plates 296 to cover the openings of the nozzles 25 while uncover the openings of the pipes 27. Then, the second reaction gas, e.g. oxygen gas (O₂), is introduced into the second room 231 and further enters into the reaction chamber 126 through the pipes 27, then reacting with the common reaction gas in the reaction chamber 126. Thus, a second coating can be deposited on the first coating. In this embodiment, the reaction forming the second coating may be expressed as follows: SiH₄+O₂═SiO₂+2H₂. Therefore, two different coatings can be formed to the same workpieces in the same coating apparatus 100. Note that the first reaction and the second reaction described above can be performed in successive turns, thus more coatings can be formed on the workpieces. Further, more than two reaction gases may be used to create more than two different kinds of coatings.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the invention to the full extent indicated by the broad general meaning of the terms in which the appended claims are expressed.

What is claimed is:

1. A coating apparatus for coating a plurality of workpieces, comprising:
a deposition chamber comprising a housing, the housing defining a cavity;
a reaction assembly received in the cavity and being coaxial with the deposition chamber, the reaction assembly comprising an outer barrel, an inner barrel, a plurality of nozzles, and a plurality of pipes, the housing and the outer barrel cooperatively defining a reaction chamber therebetween, the reaction chamber configured for receiving a common gas, the outer barrel comprising a main body and two protruding portions, the two protruding portions extending from the main body and configured for holding the workpieces, the main body and the inner barrel cooperatively defining a first room therebetween for receiving a first gas, the inner barrel defining a second room therein for receiving a second gas, the pipes extending from the inner barrel and communicating the second room with the reaction chamber, the nozzles extending from the main body and communicating the first room with the reaction chamber; and
a driving assembly connected to the reaction assembly and configured for rotating the reaction assembly in the cavity.

2. The coating apparatus as claimed in claim 1, wherein the housing has a hexagonal cross-section and comprises a bottom wall, a top wall opposite to the bottom wall, and six connection sidewalls connecting the top wall to the bottom wall.

3. The coating apparatus as claimed in claim 2, wherein the bottom wall defines a first through hole, the driving assembly comprises a first stator and a first rotor extending from the first stator, the first stator is fixed outside the deposition chamber, the first rotor engages with the first through hole so that the driving assembly is connected to the reaction assembly.

4. The coating apparatus as claimed in claim 2, wherein the deposition chamber further comprises a cover, the cover comprises a discoid body, a first flange extended from the discoid body, and a second flange extended from the first flange, the first flange and the second flange are concentric with the discoid body, the diameter of the first flange is smaller than that of the body, but larger than the diameter of the second flange.

5. The coating apparatus as claimed in claim 4, wherein the top wall defines an opening communicating with the cavity, the diameter of the discoid body is substantially equals to that of the opening, the discoid body covers the housing and seals the opening.

6. The coating apparatus as claimed in claim 4, wherein the cover comprises two heaters mounted on the discoid body and receiving in the reaction chamber.

7. The coating apparatus as claimed in claim 4, wherein the cover further defines six gas inlets defined through the first annular flange, the second annular flange and the discoid body, for receiving six gas pipes therein, the six gas pipes comprises two first gas pipes for letting in the first gas to the first room, two second gas pipes for letting in the second gas to the second room, and two vacuum pipes, the vacuum pipes insert into the protruding portions correspondingly and are configured for applying a suction to hold the workpieces on the protruding portions.

8. The coating apparatus as claimed in claim 7, wherein the outer barrel comprises a bottom plate, the main body perpendicularly extends from the bottom plate, the main body comprises a first sidewall, a second sidewall, a third sidewall, a fourth sidewall, a fifth sidewall, and a sixth sidewall connected to each other end to end, the first sidewall is approximately parallel to the fourth sidewall, the second sidewall is approximately parallel to the fifth sidewall, the third sidewall is approximately parallel to the sixth sidewall, the protruding portions extend from the first sidewall and the fourth sidewall correspondingly.

9. The coating apparatus as claimed in claim 8, wherein each protruding portion defines a plurality of receiving grooves on an outer surface thereof for receiving the workpieces, each receiving groove defines a vacuum hole on the bottom surface thereof, the vacuum holes of each protruding portion are communicated with a corresponding vacuum pipe.

10. The coating apparatus as claimed in claim 8, wherein the second sidewall and the fifth sidewall define a plurality of second through holes corresponding to the respective nozzles, the first room communicates with the reaction chamber through the second through holes and the nozzles.

11. The coating apparatus as claimed in claim 8, wherein the inner barrel comprises a hollow cylinder body, the cylinder body defines the second room, the cylinder body further defines a plurality of third through holes communicating with the second room, the third through holes arranged in two lines, respectively corresponding to the third sidewall and the sixth sidewall, the second room communicates with the reaction chamber through the third through holes and the pipes.

12. The coating apparatus as claimed in claim 11, wherein the pipes comprises first pipes and second pipes, the first pipes arranged along a first line and extending from the third sidewall toward and terminating at the corresponding third through holes, the second pipes arranged along a second line and extending from the sixth sidewall toward and terminating at the corresponding third through holes.

13. The coating apparatus as claimed in claim 8, wherein the reaction assembly further comprises four shielding members, each shielding member comprises a connecting rod, an actuator, a lead cap, and a shielding plate, the connecting rod is fixedly connected to an outer surface of a corresponding protruding portion and is bent toward an sidewall adjacent to the outer surface, the actuator comprises a second stator and a second rotor extending from the second stator, the second stator is fixedly connected to the connecting rod, the second rotor is a lead screw, the lead cap is fixed on the shielding plate, the shielding plate faces a corresponding one of the second sidewall, the sixth sidewall, the third sidewall, and the fifth sidewall and is configured for covers a line of pipes or a line of nozzles, the second rotor threadedly engages with the screw cap.

14. The coating apparatus as claimed in claim 1, further comprising a controller configured for controlling the pipes to introduce the first reaction gas to the first room or controlling the nozzles to introduce the second reaction gas to the second room.

15. A coating apparatus for coating a plurality of workpieces, comprising:
a deposition chamber comprising a housing, the housing defining a cavity;
a reaction assembly received in the cavity and being coaxial with the deposition chamber, the reaction assembly comprising an outer barrel, an inner barrel, a plurality of nozzles, and a plurality of pipes; the housing and the outer barrel cooperatively defining a reaction chamber therebetween, the reaction chamber configured for receiving a kind of common gas, the outer barrel comprising a main body and two protruding portions, the two protruding portions extending from the main body for receiving the workpieces, the main body and the inner barrel cooperatively defining a first room therebetween, the first room configured for receiving a kind of first gas, the inner barrel defining a second room therein, the second room configured for receiving a kind of second gas; the second room communicating with the reaction chamber through the pipes, the nozzles extending from the main body and communicating the first room with the reaction chamber;
a driving assembly connected to the reaction assembly and configured for driving the reaction assembly to rotate relative to the housing; and
a controller electrically connected to the reaction assembly and the driving assembly, the controller configured for controlling the driving assembly to drive the reaction assembly, and controlling the pipes to introduce the first reaction gas to the first room or controlling the nozzles to introduce the second reaction gas to the second room.
